(19) United States
(12) Patent Application Publication
(10) Pub. No.: US 2018/0083628 A1
(43) Pub. Date: Mar. 22, 2018

(54) SIGNAL PROCESSING DEVICES AND METHODS

(71) Applicant: MediaTek Singapore Pte. Ltd., Singapore (SG)

(72) Inventors: Yiming TANG, Singapore (SG); Bo HU, Singapore (SG); Kun LAN, Singapore (SG)

(21) Appl. No.: 15/707,357

(22) Filed: Sep. 18, 2017

(30) Foreign Application Priority Data
Sep. 22, 2016 (CN) 201610842146.X

(51) Int. Cl. H03K 19/0175; H03K 19/0185; G05F 1/08; H04L 25/02

(52) U.S. Cl. CPC H03K 19/017545; H04L 25/0286; G05F 1/08; H03K 19/018507

(57) ABSTRACT

A pre-driver circuit is provided. The pre-driver circuit includes a switch circuit, a common-mode voltage control circuit, and a current supply circuit. The switch circuit receives differential input signals, outputs differential output signals, and controls switching between a high level and a low level of the differential output signals and the differential input signals. The common-mode voltage control circuit is coupled to the switch circuit. The common-mode voltage control circuit receives a reference voltage and controls a common-mode voltage of the differential output signals according to the reference voltage. The current supply circuit is coupled to the switch circuit and the common-mode voltage control circuit. The current supply circuit provides a driving current for the switch circuit and the common-mode voltage control circuit.

### CROSS REFERENCE TO RELATED APPLICATIONS

This Application claims priority of China Patent Application No. 201610842146.X, filed on Sep. 22, 2016, the entirety of which is incorporated by reference herein.

### BACKGROUND OF THE INVENTION

### Field of the Invention

The invention relates to high-speed transmission, and more particularly, to a pre-driver circuit.

### Description of the Related Art

FIG. 1 is a schematic diagram illustrating a structure of a current high-speed signal transmission module. As shown in FIG. 1, the transmission module 10 comprises a serialization circuit 1, a pre-driver circuit 2, and a driver circuit 3 which are coupled sequentially.

The serialization circuit 1 is configured to convert parallel high-speed data signals to serial differential signals. The pre-driver circuit 2 and the driver circuit 3 are configured to perform a conversion operation on the differential signals, so that the differential signals can be applied for various kinds of interfaces, such as a display port (DP), a high definition multimedia interface (HDMI), a mobile high-definition link (MHL), a universal serial bus (USB), and so on.

The current pre-driver circuit 2 can be a current mode logic (CML) circuit, a voltage mode logic (VML) circuit, and so on.

In cases where differential output signals have the same swing, compared to a pre-driver circuit 2 adopting VML circuit, the common-mode voltage of the differential output signals of a pre-driver circuit 2 adopting CIVIL circuit is not adjustable, and the pre-driver circuit 2 adopting VML circuit requires two additional buffers for providing reference voltages, which results in a larger circuitry area.

### BRIEF SUMMARY OF THE INVENTION

Thus, the present invention provides a pre-driver circuit.

An exemplary embodiment of a pre-driver circuit is provided. The pre-driver circuit comprises a switch circuit, a common-mode voltage control circuit, and a current supply circuit. The switch circuit receives differential input signals, outputs differential output signals, and controls switching between a high level and a low level of the differential output signals and the differential input signals. The common-mode voltage control circuit is coupled to the switch circuit. The common-mode voltage control circuit receives a reference voltage and controls a common-mode voltage of the differential output signals according to the reference voltage. The current supply circuit is coupled to the switch circuit and the common-mode voltage control circuit. The current supply circuit provides a driving current for the switch circuit and the common-mode voltage control circuit.

According to the above embodiment, the pre-driver circuit of the first embodiment controls the common-mode voltage of the differential output signals through the common-mode voltage control circuit, so that the common-mode voltage is adjustable. Moreover, the common-mode voltage control circuit just needs a reference voltage for accomplishing the adjustment of the common-mode voltage. Thus, the structure of the common-mode voltage control circuit is simplified, thereby reducing the area occupied by the pre-driver circuit.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 is a schematic diagram illustrating a structure of a current high-speed signal transmission module;

FIG. 2 is a schematic diagram illustrating a pre-driver circuit according to a first embodiment;

FIG. 3 is a schematic diagram illustrating a pre-driver circuit according to a second embodiment;

FIG. 4 is a schematic diagram showing a typical CIVIL circuit; and

FIG. 5 is a schematic diagram showing a typical VML circuit.

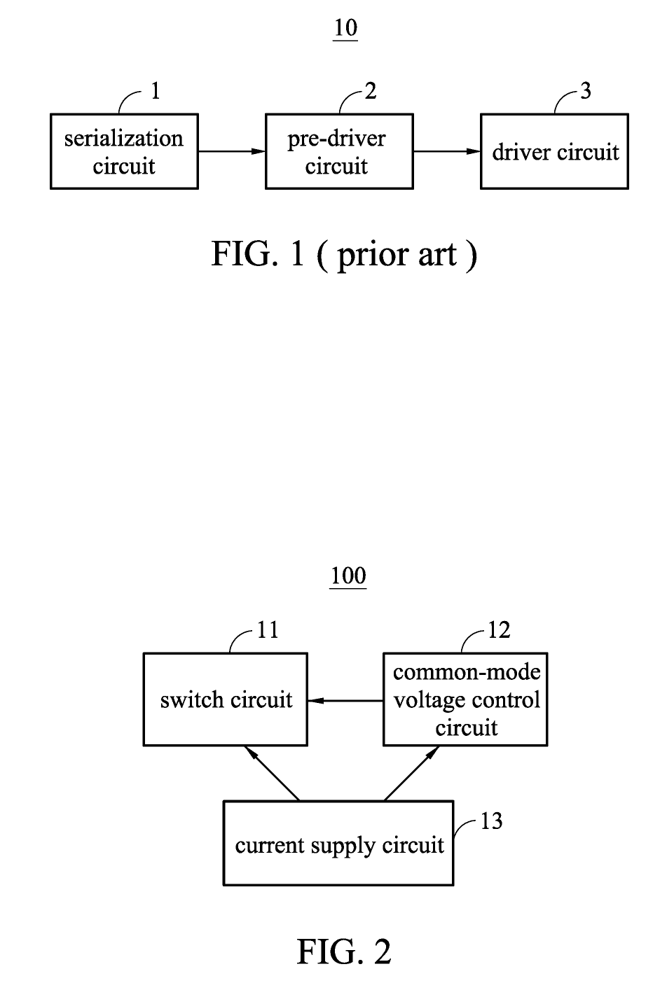

### DETAILED DESCRIPTION OF THE INVENTION

Certain terms are used throughout the specification and following claims to refer to particular components. As one skilled in the art will appreciate, manufacturers may refer to a component by different names. The specification and following claims do not intend to distinguish between components that differ in name but not function. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if a first device couples to a second device, that connection may be through a direct electrical connection, through an indirect electrical connection via other devices and connections.

To better understand the technical aspect of the present invention, the following embodiments of the invention will be described in detail by referring to the drawings.

FIG. 2 is a schematic diagram illustrating a pre-driver circuit according to a first embodiment. As shown in FIG. 2, the pre-driver circuit 100 comprises a switch circuit 11, a common-mode voltage control circuit 12, and a current supply circuit 13.

The switch circuit 11 is configured to receive differential input signals, output differential output signals, and control switching between a high level and a low level for the output differential output signals based on the differential input signals.

The common-mode voltage control circuit 12 is coupled to the switch circuit 11 and configured to receive a reference voltage and control a common-mode voltage of the differential output signals according to the reference voltage.

The current supply circuit 13 is coupled to the switch circuit 11 and the common-mode voltage control circuit 12 and configured to provide a driving current for the switch circuit 11 and the common-mode voltage control circuit 12.

According to the above embodiment, the pre-driver circuit of the first embodiment controls the common-mode voltage of the differential output signals through the common-mode voltage control circuit, such that the common-mode voltage is adjustable. Moreover, the common-mode voltage control circuit only needs a reference voltage for accomplishing the adjustment of the common-mode voltage. Thus, the structure of the common-mode voltage control circuit is simplified, thereby reducing the area occupied by the pre-driver circuit.

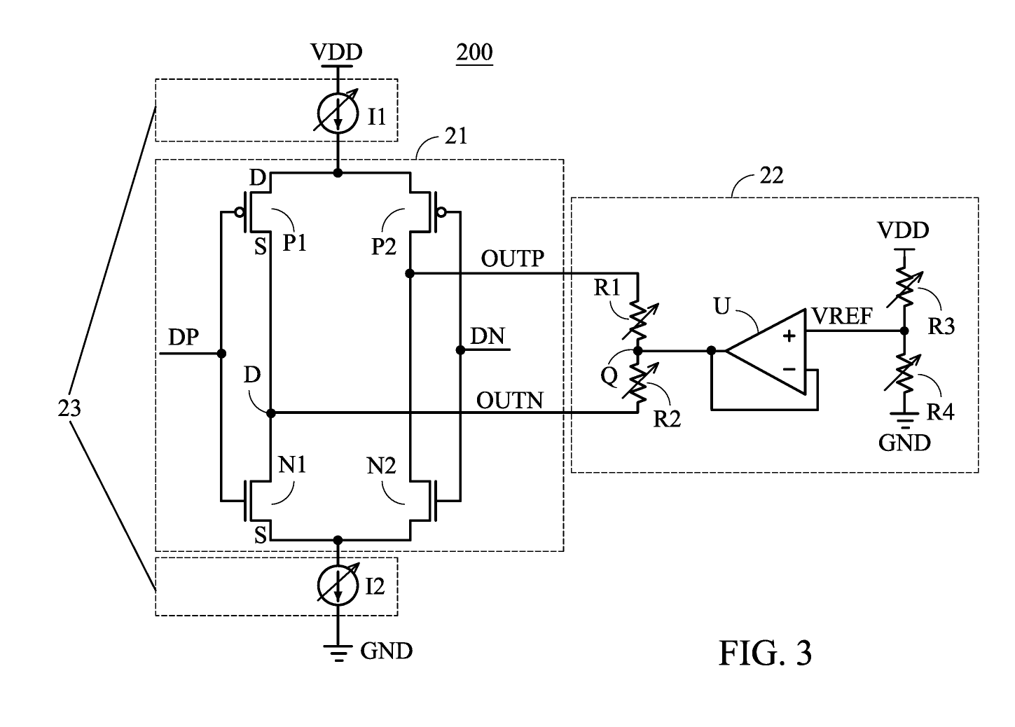

FIG. 3 is a schematic diagram illustrating a pre-driver circuit according to a second embodiment. As shown in FIG. 3, the pre-driver circuit 200 comprises a switch circuit 21, a common-mode voltage control circuit 22, and a current supply circuit 23.

The switch circuit 21 is configured to control switching between a high level and a low level for output differential output signals OUTP and OUTN based on differential input signals DP and DN. The common-mode voltage control circuit 22 is coupled to the switch circuit 21 and configured to control a common-mode voltage Vcom (not shown in FIG. 3) of the differential output signals OUTP and OUTN. The current supply circuit 23 is coupled to the switch circuit 21 and the common-mode voltage control circuit 22 and configured to provide a driving current for the switch circuit 21 and the common-mode voltage control circuit 22.

The switch circuit 21 comprises a first P-type metal-oxide-semiconductor (PMOS) transistor P1, a second PMOS transistor P2, a first N-type metal-oxide-semiconductor (NMOS) transistor N1, and a second NMOS transistor N2. The common-mode voltage control circuit 22 comprises a first resistor R1 and a second resistor R2. In the embodiment, the current supply circuit 23 comprises a first current source I1 and a second current source I2, but not limited thereto.

In the embodiment, the gates of the first PMOS transistor P1 and the second PMOS transistor P2 receive the differential input signals DP and DN respectively. The sources of the first PMOS transistor P1 and the second PMOS transistor P2 output the differential output signals OUTP and OUTN respectively. Specifically, the gate of the first PMOS transistor P1 is coupled to the differential input signal DP, and the gate of the second PMOS transistor P2 is coupled to the differential input signal DN. The source of the first PMOS transistor P1 is coupled to the differential output signal OUTN, and the source of the second PMOS transistor P2 is coupled to the differential output signal OUTP.

The gates of the first NMOS transistor N1 and the second NMOS transistor N2 are coupled to the gates of the first PMOS transistor P1 and the second PMOS transistor P2, respectively. The drains of the first NMOS transistor N1 and the second NMOS transistor N2 are coupled to the sources of the first PMOS transistor P1 and the second PMOS transistor P2, respectively.

The drains of the first PMOS transistor P1 and the second PMOS transistor P2 are coupled together and then coupled to the current supply circuit 23. The sources of the first NMOS transistor N1 and the second NMOS transistor N2 are coupled together and then coupled to the current supply circuit 23. Specifically, the drains of the first PMOS transistor P1 and the second PMOS transistor P2 are coupled together and then coupled to the negative terminal of the first current source I1, and the positive terminal of the first current source I1 is coupled to the power source VDD. The sources of the first NMOS transistor N1 and the second NMOS transistor N2 are coupled together and then coupled to the positive terminal of the second current source I2, and the negative terminal of the second current source I2 is coupled to the ground GND.

In the embodiment, preferably, the first current source I1 and the second current source I2 are adjustable current sources.

One terminal of the first resistor R1 is coupled to the source of the second PMOS transistor P2. The other terminal of the first resistor R1 is coupled to one terminal of the second resistor R2 at a common node Q. The other terminal of the second resistor R2 is coupled to the source of the first PMOS transistor P1.

In the embodiment, preferably, the first resistor R1 and the second resistor R2 are variable resistors.

Preferably, in the embodiment, the common-node voltage control circuit 22 further comprises a buffer U, a third resistor R3, and a fourth resistor R4. The buffer U comprises a non-inverting input terminal +, an inverting input terminal −, and an output terminal. The non-inverting input terminal + of the buffer U is coupled to one terminal of the third resistor R3 and one terminal of the fourth resistor R4 for receiving a reference voltage VREF. The inverting input terminal − and the output terminal of the buffer U are coupled together at the node Q. The other terminal of the third resistor R3 is coupled to the power source VDD. The other terminal of the fourth resistor R4 is coupled to the ground GND.

In the embodiment, the reference voltage is obtained based on the following equation.

$$VREF = \frac{VDD}{R 3 + R 4} \times R 4$$

Preferably, the third resistor R3 and the fourth resistor R4 are variable resistors, such that the reference voltage VREF is adjustable.

The operation of the pre-driver circuit 200 will be described in the following. When the voltages of the differential input signals DP and DN are at high-level voltage VH1 and low-level voltage VL1 respectively, the first PMOS transistor P1 and the second NMOS transistor N2 are turned off, and the second PMOS transistor P2 and the first NMOS transistor N1 are turned on, so that the current output from the first current source I1 flows through the second PMOS transistor P2, the first resistor R1, the second resistor R2, and the first NMOS transistor N1 and then finally to the second current source I2. At this time, the voltage of the differential output signals OUTP and OUTN are at high-level voltage VH2 and low-level voltage VL2 respectively.

Moreover, when the voltages of the differential input signals DP and DN are inverted, that is, when they are respectively at the low-level voltage VL1 and the high-level voltage VH1, the second PMOS transistor P2 and the first NMOS transistor N1 are turned off, and the first PMOS transistor P1 and the second NMOS transistor N2 are turned on, so that the current output from the first current source I1 flows through the first PMOS transistor P1, the second resistor R2, the first resistor R1, and the second NMOS transistor N2 and then finally to the second current source I2. At this time, the voltage of the differential output signals OUTP and OUTN are at the low-level voltage VL2 and the high-level voltage VH2, respectively.

In the embodiment, the common-mode voltage Vcom of the differential output signals OUTP and OUTN are adjustable. The common-mode voltage is adjusted according to the reference voltage VREF.

Specifically, the common-mode voltage Vcom is the average of the voltage of the differential output signal OUTP and the voltage of the differential output signal OUTN, shown as:

$$Vcom = \frac{VH 2 + VL 2}{2}$$

When the pre-driver circuit 200 operates normally, the current flowing through the first resistor R1 is equal to the current flowing through the second resistor R2. In cases where the resistance of the first resistor R1 is equal to the resistance of the second resistor R2, the following equation is obtained.

$$\frac{VH 2 - VREF}{R} = \frac{VREF - VL 2}{R}$$

That is Vcom=VREF

Vcom represents the common-mode voltage of the differential output signals OUTP and OUTN. VL2 and VH2 represent the low-level voltage and the high-level voltage of the differential output signals OUTP and OUTN respectively. VREF represents the reference voltage. R represents the resistance of the first resistor R1 or the second resistor R2.

In the embodiment, the swing I_{swing} of the differential output signals OUTP and OUTN is adjustable. The swing I_{swing} is adjusted according to the first resistor R1, the second resistor R2, the first current source I1, and the second current source I2.

Preferably, in cases where the resistance of the first resistor R1 is equal to the resistance of the second resistor R2 and the value of the driving current provided by the first current source I1 is equal to the value of the driving current provided by the second current source I2, the swing I_{swing} of the differential output signals OUTP and OUTN is calculated according to the following equation:

I_{swing}=2*I_{S}*R

I_{swing} represents the swing of the differential output signals OUTP and OUTN. I_{S} represents the value of the driving current provided by the first current source I1 or the second current source I2. R represents the resistance of the first resistor R1 or the second resistor R2.

In the embodiment, the time constant τ of the differential output signals OUTP and OUTN is adjustable. The time constant τ is adjusted according to the first resistor R1 and the second resistor R2. One skilled in the art will understand that the time constant determines the speed of the high-speed signal transmission supported by the pre-driver circuit. In other words, the smaller the time constant is, the higher the speed of the high-speed signal transmission supported by the pre-driver circuit is.

Preferably, in cases where the resistance of the first resistor R1 is equal to the resistance of the second resistor R2 and the model number of the first PMOS transistor P1 is the same as the model number of the second PMOS transistor P2, the time constant τ is calculated according to the following equation:

τ=R*C_{P}

wherein, τ represents the time constant of the differential output signals OUTP and OUTN. R represents the resistance of the first resistor R1 or the second resistor R2. C_{P} represents the parasitic capacitance of the first PMOS transistor P1 or the second PMOS transistor P2.

A specific embodiment will be described below. It is assumed that the pre-driver circuit 200 requires the differential output signals with an output swing of 600 mV. In this case, when the resistance R of the first resistor R1 and the second resistor R2 is determined to be 50Ω, the value I_{S} of the driving current provided by the first current source I1 and the second current source I2 is requested to be equal to 6 mA.

As described above, the common-mode voltage Vcom in the pre-driver circuit 200 is adjustable. Thus, if the high-level voltage VH2 and the low-level voltage VL2 of the differential output signals have to be equal to 1V and 0.4V respectively, that is, if the common-mode voltage Vcom′ has to be equal to 0.7V, then only the reference voltage VREF is requested to be equal to 0.7V.

Moreover, the time constant of the pre-driver circuit 200 is smaller, thus, the pre-driver circuit 200 can support a higher speed of signal transmission. Specifically, the time constant is 50C_{P}, wherein C_{P} represents the parasitic capacitance of the first PMOS transistor P1 or the second PMOS transistor P2.

In the following, the comparison between a typical CML circuit, a typical VML, and the pre-driver circuit 200 of the second embodiment will be described.

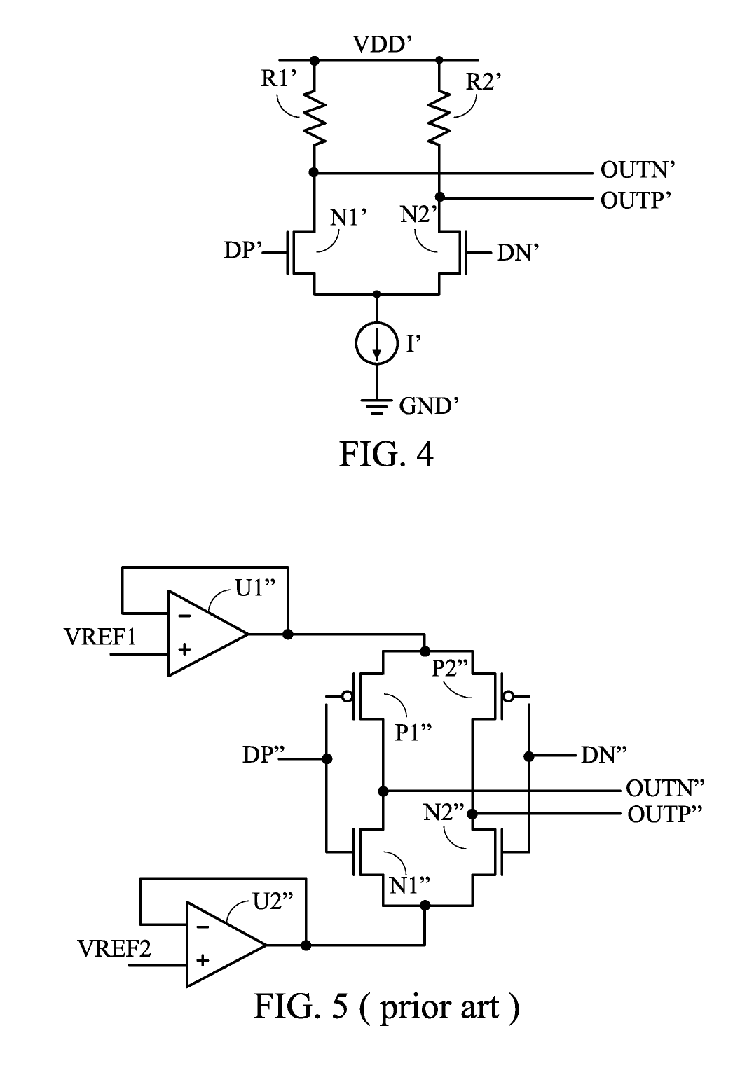

Referring to FIG. 4, FIG. 4 is a schematic diagram showing a typical CML circuit. As shown in FIG. 4, the CIVIL circuit comprises a first resistor R1′, a second resistor R2′, a first NMOS transistor N1′, a second NMOS transistor N2′, and a current source I′. The gates of the first NMOS transistor N1′ and the second NMOS transistor N2′ receive differential output signals DP′ and DN′ respectively. The sources of the first NMOS transistor N1′ and the second NMOS transistor N2′ are coupled together and then coupled to the positive terminal of the current source I′. The negative terminal of the current source I′ is coupled to the ground GND′. The drains of the first NMOS transistor N1′ and the second NMOS transistor N2′ are coupled to one terminal of the first resistor R1′ and one terminal of the second resistor R2′ respectively. The other terminal of the first resistor R1′ and the other terminal of the second resistor R2′ are coupled together and then coupled to the power source VDD′. The drains of the first NMOS transistor N1′ and the second NMOS transistor N2′ output the differential output signals OUTP′ and OUTN′ respectively.

Assume that the CML circuit needs to output differential output signals with a swing of 600 mV. When the resistance of the first resistor R1′ and the second resistor R2′ is determined to be 50Ω, the value of the driving current provided by the current source I′ is requested to be equal to 12 mA. That is, compared with the pre-driver circuit 200, the CML circuit consumes more current.

In the CIVIL circuit, the common-mode voltage Vcom′ of the differential output signals is not adjustable, and it is obtained through the following equation.

Vcom′=V′−50×0.012÷2=V′−0.3

V′ represents the voltage provided by the power source VDD′.

If the high-level voltage and the low-level voltage of the differential output signals need to be equal to 1V and 0.4V respectively, that is, if the common-mode voltage Vcom′ need be equal to 0.7V, the voltage of the power source VDD′ is requested to be 1V.

Moreover, the time constant of the CML circuit is smaller. Specifically, the time constant is 50C_{P}, wherein C_{P} represents the parasitic capacitance of the first NMOS transistor N1′ or the second NMOS transistor N2′.

Referring to FIG. 5, FIG. 5 is a schematic diagram showing a typical VML circuit. As shown in FIG. 5, the VML circuit comprises a first buffer U1″, a second buffer U2″, a first PMOS transistor P1″, a second PMOS transistor P2″, a first NMOS transistor N1″, and a second NMOS transistor N2″. Wherein, in this embodiment, in the VML circuit, the gates of the first PMOS transistor P1″ and the second PMOS transistor P2″ receives differential input signals DP″ and DN″ respectively. The sources of the first PMOS transistor P1″ and the second PMOS transistor P2″ generate differential output signal OUTP″ and OUTN″ respectively. The gates of the first NMOS transistor N1″ and the second NMOS transistor N2″ are coupled to the gates of the first PMOS transistor P1″ and the second PMOS transistor P2″ respectively. The drains of the first NMOS transistor N1″ and the second NMOS transistor N2″ are coupled to the sources of the first PMOS transistor P1″ and the second PMOS transistor P2″ respectively. The drains of the first PMOS transistor P1″ and the second PMOS transistor P2″ are coupled together and then coupled to the output terminal of the first buffer U1″. The non-inverting input terminal + of the first buffer U1″ receives a first reference voltage VREF1, and the inverting input terminal − of the first buffer U1″ is coupled to the output terminal of the first buffer U1″. The sources of the first NMOS transistor N1″ and the second NMOS transistor N2″ are coupled together and then coupled to the output terminal of the second buffer U2″. The non-inverting input terminal + of the second buffer U2″ receives a second reference voltage VREF2, and the inverting input terminal − of the second buffer U2″ is coupled to the output terminal of the second buffer U2″.

Assumed the VML circuit needs to output differential output signals with a swing of 600 mV. Compared with the CML circuit and the pre-driver current 200, the VML circuit consumes more current due to the existence of the first buffer U1″ and the second buffer U2″. Moreover, due to the existence of the first buffer U1″ and the second buffer U2″, the occupation area of the circuit board is increased.

In the VML circuit, the common-mode voltage Vcom″ is adjustable. The common-mode voltage Vcom″ is determined by the first reference voltage VREF1 and the second reference voltage VREF2. If the high-level voltage and the low-level voltage of the differential output signals need to be equal to 1V and 0.4V respectively, that is, if the common-mode voltage Vcom″ has to be equal to 0.7V, only the first reference voltage VREF1 needs to be 1V and the second reference voltage VREF2 needs to be 0.4V.

Compared with the CML circuit and the pre-driver circuit 200, the time constant of the CIVIL circuit is larger. Specifically, the time constant is (1/gm)*C_{P}″, wherein C_{P}″ represents the parasitic capacitance of the first PMOS transistor P1″ or the second PMOS transistor P2″. gm represents the transconductance.

As described above, the pre-driver circuit 200 have the advantages of both the CML circuit and the VML circuit. The pre-driver circuit 200 is a circuit with its common-mode voltage adjustable, circuit area is smaller, power consumption is reduced, and time constant of the differential output signals is smaller.

Through the above embodiment, the pre-driver circuit disclosed in the second embodiment controls the common-mode voltage of the differential output signals through the common-mode voltage control circuit, so that the common-mode voltage is adjustable. The circuit area of the pre-driver circuit is significantly decreased by using only the reference voltage provided by the buffer. The pre-driver circuit provides driving current through two current sources, so that the current consumption in the circuit is lower. The time constant of the pre-driver circuit is determined by the resistance of the first or second resistor and the parasitic capacitance of the first or second PMOS transistor, so that the time constant is smaller, which supports a much faster signal transmission.

While the invention has been described by way of example and in terms of the preferred embodiments, it is to be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A pre-driver circuit comprising:
a switch circuit, receiving differential input signals, outputting differential output signals, and controlling switching between a high level and a low level of the differential output signals and the differential input signals;
a common-mode voltage control circuit, coupled to the switch circuit, receiving a reference voltage and controlling a common-mode voltage of the differential output signals according to the reference voltage; and
a current supply circuit, coupled to the switch circuit and the common-mode voltage control circuit, providing a driving current for the switch circuit and the common-mode voltage control circuit.

2. The pre-driver circuit as claimed in claim 1,
wherein the switch circuit comprises a first P-type metal-oxide-semiconductor (PMOS) transistor, a second PMOS transistor, a first N-type metal-oxide-semiconductor (NMOS) transistor, and a second NMOS transistor,
wherein gates of the first PMOS transistor and the second PMOS transistor receive the differential input signals respectively, sources of the first PMOS transistor and the second PMOS transistor output the differential output signals respectively, and drains of the first PMOS transistor and the second PMOS transistor are coupled together and then coupled to the current supply circuit, and
wherein gates of the first NMOS transistor and the second NMOS transistor are coupled to the gates of the first PMOS transistor and the second PMOS transistor respectively, drains of the first NMOS transistor and the second NMOS transistor are coupled to the sources of the first PMOS transistor and the second PMOS transistor, and sources of the first NMOS transistor and the second NMOS transistor are coupled together and then coupled to the current supply circuit.

3. The pre-driver circuit as claimed in claim 2,
wherein the current supply circuit comprises a first current source and a second current source,
wherein a positive terminal of the first current source is coupled to a power source, a negative terminal of the first current source is coupled to the drains of the first PMOS transistor and the second PMOS transistor, and
wherein a positive terminal of the second current source is coupled to the sources of the first NMOS transistor and the second NMOS transistor, and a negative terminal of the second current source is coupled to a ground.

4. The pre-driver circuit as claimed in claim 3,
wherein the common-mode voltage control circuit comprises a first resistor and a second resistor,
wherein one terminal of the first resistor is coupled to the source of the second PMOS transistor, the other terminal of the first resistor is coupled to one terminal of the second resistor at a common node, and the other terminal of the second resistor is coupled to the source of the first PMOS transistor, and
wherein the common node is coupled to the reference voltage.

5. The pre-driver circuit as claimed in claim 4,
wherein the common-mode voltage control circuit further comprises a buffer,
wherein the buffer is coupled between the common node and the reference voltage,
wherein the buffer comprises a non-inverting input terminal, an inverting input terminal, and an output terminal, and
wherein the non-inverting input terminal of the buffer is coupled to the reference voltage, and the inverting input terminal and the output terminal of the buffer are coupled together and then coupled to the common node.

6. The pre-driver circuit as claimed in claim 5, wherein the common-mode voltage of the differential output signals is adjustable, and the common-mode voltage is adjusted according to the reference voltage.

7. The pre-driver circuit as claimed in claim 5, wherein swing of the differential output signals is adjustable, and the swing is adjusted according to the first resistor, the second resistor, the first current source, and the second current source.

8. The pre-driver circuit as claimed in claim 7,
wherein when a resistance of the first resistor is equal to a resistance of the second resistor and a value of a driving current provided by the first current source is equal to a value of a driving current provided by the second current source, the swing of the differential output signals is calculated according to an equation:
I_{swing}=2*I_{S}*R
wherein I_{swing} represents the swing of the differential output signals, I_{S} represents the value of the driving current provided by the first current source or the second current source, and R represents the resistance of the first resistor or the second resistor.

9. The pre-driver circuit as claimed in claim 5, wherein a time constant of the differential output signals is adjustable, and the time constant is adjusted according to the first resistor and the second resistor.

10. The pre-driver circuit as claimed in claim 9,
wherein when a resistance of the first resistor is equal to a resistance of the second resistor and a model number of the first PMOS transistor is the same as a model number of the second PMOS transistor, the time constant is calculated according to an equation:
τ=R*C_{P}
wherein τ represents the time constant of the differential output signals, R represents the resistance of the first resistor or the second resistor, and C_{P} represents a parasitic capacitance of the first PMOS transistor or the second PMOS transistor.

11. The pre-driver circuit as claimed in claim 5,
wherein the common-mode voltage control circuit further comprises a third resistor and a fourth resistor,
wherein one terminal of the third resistor is coupled to the power source, the other terminal of the third resistor and one terminal of the fourth resistor are coupled together to provide the reference voltage, and the other terminal of the fourth resistor is coupled to the ground.
